(19) United States
(12) Patent Application Publication
(10) Pub. No.: US 2014/0210482 A1
(43) Pub. Date: Jul. 31, 2014

(54) METHOD AND APPARATUS FOR REDUCING COMMON MODE VARIATIONS IN A VOLTAGE SENSING COMPONENT

(71) Applicant: QUALCOMM INCORPORATED, San Diego, CA (US)

(72) Inventors: Baiying Yu, Santa Clara, CA (US); Brett C. Walker, San Diego, CA (US)

(73) Assignee: QUALCOMM Incorporated, San Diego, CA (US)

(21) Appl. No.: 13/752,314

(22) Filed: Jan. 28, 2013

(51) Int. Cl. G01R 31/36

(52) U.S. Cl. CPC G01R 31/362
USPC 324/433

(57) ABSTRACT

A method and apparatus that reduce common mode variations experienced by a voltage sensing component. A measurement component such as a BATFET or an external sensing resistor, receives, at its source, a voltage from the top of a battery having a voltage VPH_PWR. A voltage sensing component, such as an ADC, is powered by the voltage from the battery. A power referenced component, such as a power referenced LDO, tracks the voltage from the battery and outputs the tracked voltage minus a predetermined voltage amount to a negative side of the voltage sensing component.

### BACKGROUND

1. Field

The present disclosure relates generally to a method and apparatus for reducing common mode variations experienced by a voltage sensing component, such as a switched-cap sigma delta Analog-to-Digital Converter (ADC) that can be used, e.g., in a fuel gauge for a communication device.

2. Background

Wireless communication systems are widely deployed to provide various telecommunication services such as telephony, video, data, messaging, and broadcasts. Typical wireless communication systems may employ multiple-access technologies capable of supporting communication with multiple users by sharing available system resources (e.g., bandwidth, transmit power). Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example of an emerging telecommunication standard is Long Term Evolution (LTE). LTE is a set of enhancements to the Universal Mobile Telecommunications System (UMTS) mobile standard promulgated by Third Generation Partnership Project (3GPP). It is designed to better support mobile broadband Internet access by improving spectral efficiency, lower costs, improve services, make use of new spectrum, and better integrate with other open standards using OFDMA on the downlink (DL), SC-FDMA on the uplink (UL), and multiple-input multiple-output (MIMO) antenna technology. However, as the demand for mobile broadband access continues to increase, there exists a need for further improvements in LTE technology. Preferably, these improvements should be applicable to other multi-access technologies and the telecommunication standards that employ these technologies.

A battery fuel level in a battery operated device can be monitored using voltage sensing circuitry. However, when the battery operated apparatus is in operation, dips in battery voltage may occur. For example, when a battery operated user equipment (UE) functions in a Global System for Mobile Communications (GSM) mode, i.e. in a talk mode, such communication involves GSM bursts. During GSM bursts, a dip in the UE's battery voltage occurs. The voltage change during such a dip can be as high as 700 mV. Such drops in the battery voltage cause a high offset to occur in voltage sensing circuitry due to a limited common mode rejection ratio (CMRR), leading to an inaccurate measurement of the fuel level of the battery.

Thus, a need exists for a reduction in common mode variations experienced by voltage sensing circuitry for such battery operated devices.

### SUMMARY

In an aspect of the disclosure, a method and apparatus are provided that reduce common mode variations experienced by a voltage sensing component. A measurement component such as a BATFET or an external sensing resistor, receives, at its source, a voltage from the top of a battery having a voltage VPH_PWR. A voltage sensing component, such as an Analog-to-Digital Converter (ADC), is powered by the voltage from the battery. A power referenced component, such as a power referenced LDO, tracks the voltage from the battery and outputs the tracked voltage minus a predetermined voltage amount to a negative side of the voltage sensing component.

A first voltage is received from the top side of a battery at a source of a measurement component. The measurement component outputs a second voltage to a power referenced component, wherein the second voltage tracks the first voltage. The power referenced component outputs a third voltage to a voltage sensing component, the third voltage being equal to the second voltage less a predetermined voltage amount. Thereafter, the voltage sensing component is powered between the first voltage and the second voltage.

Aspects may be used, e.g., in a fuel gauging application for a UE. The aspects described herein provide a super low offset at a low price for area and power and provides greatly improved performance.

### BRIEF DESCRIPTION OF THE DRAWINGS

FIG. 1 is a diagram illustrating an example diagram for reducing common mode variations experienced by an ADC.

FIG. 2 is a diagram illustrating example details of the diagram from FIG. 1.

FIG. 3 is a flow chart of a method of reducing a common mode variation experienced by an ADC.

FIG. 4 is a diagram illustrating an example of a hardware implementation for an apparatus employing aspects of common mode variation reduction.

FIG. 5 is a diagram illustrating an example of an evolved Node B and user equipment in an access network.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

As noted, a need exists for a reduction in common mode variations experienced by voltage sensing circuitry for battery operated devices because dips in battery voltage may occur during operation of the device. One example of such a device is a UE. Although example aspects will be described in connection with a UE, these aspects for reducing common mode variations experienced by voltage sensing circuitry may be applied to other battery operated devices as well.

One example of voltage sensing circuitry includes a fuel gauging system for monitoring the fuel level of a battery. For high end fuel gauging systems, both battery voltage and battery current are monitored closely for good performance. A super low Input Referred Offset (IRO<50 uV) in battery current sensing is desired systematically to guarantee accuracy in battery monitoring, e.g., a ±5% battery State Of Charge (SOC). Typical current sensing is done with an external sensing resistor at low side of the battery instead of a high side or top of the battery.

When a UE functions in GSM mode, i.e. in a talk mode, such communication involves GSM bursts. During such bursts, a dip in battery voltage occurs for the UE. The voltage change during such a dip can be as high as 700 mV. In turn, this dip in the battery voltage causes a high offset to occur in voltage sensing circuitry due to a limited CMRR of voltage measuring component of sense voltage.

On-chip current sensing with either a battery field effect transistor (BATFET) or a precision sensing resistor (Rₛ) makes high side current sensing very attractive since it enables a minimum routing resistance in high current path. Such minimum routing resistance improves battery efficiency, which results in a longer potential talk time. However, with high side sensing of the battery voltage, the large variation in Vbat described above makes it difficult to achieve an input referred offset of less than 50 uV, as required in order to have an input CMRR as high as 82 dB.

With conventional circuit design, the CMRR rolls off around 100 kHz to 40 dB and are not suitable to achieve ≧82 dB CMRR at the frequency of sampling clock higher than tens of kHz.

In order to reduce, e.g., eliminate, the common mode variations experienced at a front end of voltage sensing circuitry, such as an ADC, a power referenced LDO Low Dropout Regulator (LDO) is provided subsequent to the ADC that tracks the changes in the battery voltage. The LDO generates an output voltage equal to the battery voltage minus a predetermined voltage amount, which output is input to a negative side of the CCADC. For example, the LDO may output VPH_PWR−1.8V. This provides, e.g., a 1.8V power supply subsequent to the ADC. The ADC is powered by the battery voltage Vbat. By providing such an LDO, the ADC experiences a constant common mode that enables the ADC to achieve and maintain a very small offset, e.g., less than a 50 μV offset.

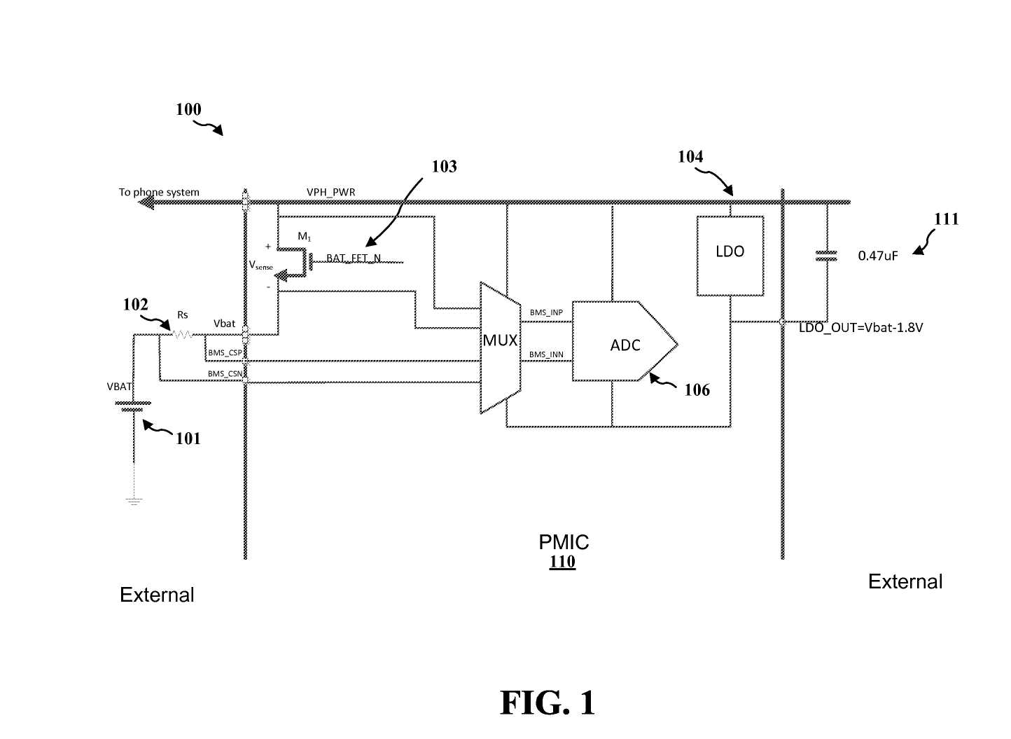

As illustrated in FIG. 1, since the whole ADC is powered by VPH_PWR, VPH_PWR−1.8V, the input common mode is always fixed at VPH_PWR or Vbat if external sensing resistor (Rₛ) is used for voltage sensing. Relative to a lower power rail of CCADC (VPH_PWR−1.8V), it is fixed at 1.8V. This way, even though the VPH_PWR might vary from 2.5V to 4.2V during GSM bursts, for example, the SC front end of ADC, maintains its input common mode at a constant. This constant can be eliminated with a single calibration. By eliminating the common mode variation seen by the ADC, the need for a high CMRR is eliminated in order to achieve the necessary 50 μV offset.

The current sensing ADC may be implemented as a switched-cap sigma delta ADC.

BATFET is a component that is typically part of charging circuitry that enables the device, e.g. UE, to either stop charging or discharging the battery if needed. As described herein, it can also be configured to measure a fuel level of the battery. The BATFET is provided on the top side or high side of the battery. Thus, a high side fuel gauge may be accomplished using the BATFET.

As illustrated in FIG. 1, the BATFET 103, ADC 106, and LDO 104 may be provided on a power management integrated circuit (PMIC) 110. A PMIC 110 may comprise integrated circuits or a system block in a system-on-a-chip device for managing power consumption. A PMIC 110 may provide battery management, voltage regulation, or charging functions, etc. As shown in FIG. 1, the battery 101 may be external to the PMIC 110, and the LDO 104 may require an external connection to the PMIC 110 for stability. For example, the LDO 104 may output its output voltage of VPH_PWR minus the predetermined voltage amount to a component 111 external to the PMIC. FIG. 1 illustrates the LDO 104 outputting LDO_OUT to an external capacitor 111.

Although examples are described in connection with a fuel gauge and a UE, the aspects described herein can be used in other applications requiring a reduction in a common mode variation for analog circuitry.

FIG. 1 illustrates an example diagram 100 for reducing a common mode rejection ratio, e.g., experienced by an ADC 106. In FIG. 1, a battery 101 is provided external to a PMIC 110. A resistor 102 and a BAT FET 103 are provided on the high side of the battery 101. At least one of the resistor 102 and the BATFET 103 measure the voltage Vbat on the high side of the battery 101. ADC 106, e.g. a CCADC, may sense the battery voltage Vbat, e.g., in order to accurately gauge the fuel level of the battery. In order to reduce potential common mode variations that could be experienced by the ADC, an LDO 104 is provided as a power referencing component that receives Vbat and outputs Vbat less a predetermined amount. In FIG. 1, LDO is illustrated as outputting Vbat−1.8V to ADC 106. ADC 106 is powered from Vbat and Vbat−1.8V. Thus, the input common mode for the ADC is always fixed at Vbat. Relative to the lower power rail of ADC 106, the common mode is fixed at 1.8V. Thus, even though Vbat provided to the front end of ADC 106 may vary, e.g. from 2.5V to 4.2V due to GSM talk bursts, the input common mode of remains at a constant. This enables a super low offset at a low price for area and power and provides improved performance.

In FIG. 1, LDO 104 connects to the exterior of the PMIC via capacitor 111.

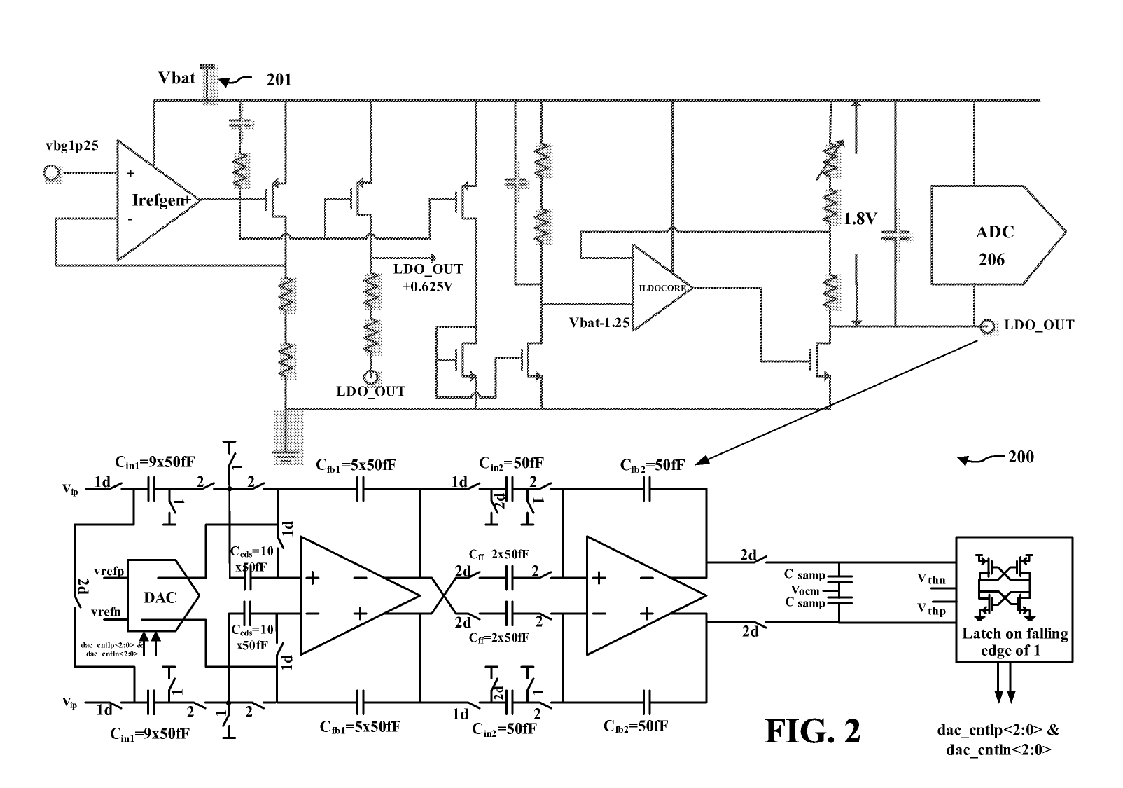

FIG. 2 illustrates an example diagram showing details of the aspects illustrated in FIG. 1. For example, FIG. 2 illustrates details of the LDO 104 illustrated in FIG. 1. In FIG. 2, LDO 200 receives Vbat from battery 201. LDO outputs LDO_OUT to ADC 206. The bandgap voltage 1.25V is the reference voltage used to generate Vbat−1.25 reference voltage which is referenced to Vbat. With Vbat−1.25 reference voltage, LDO_OUT is generated subsequently which is reference to Vbat.

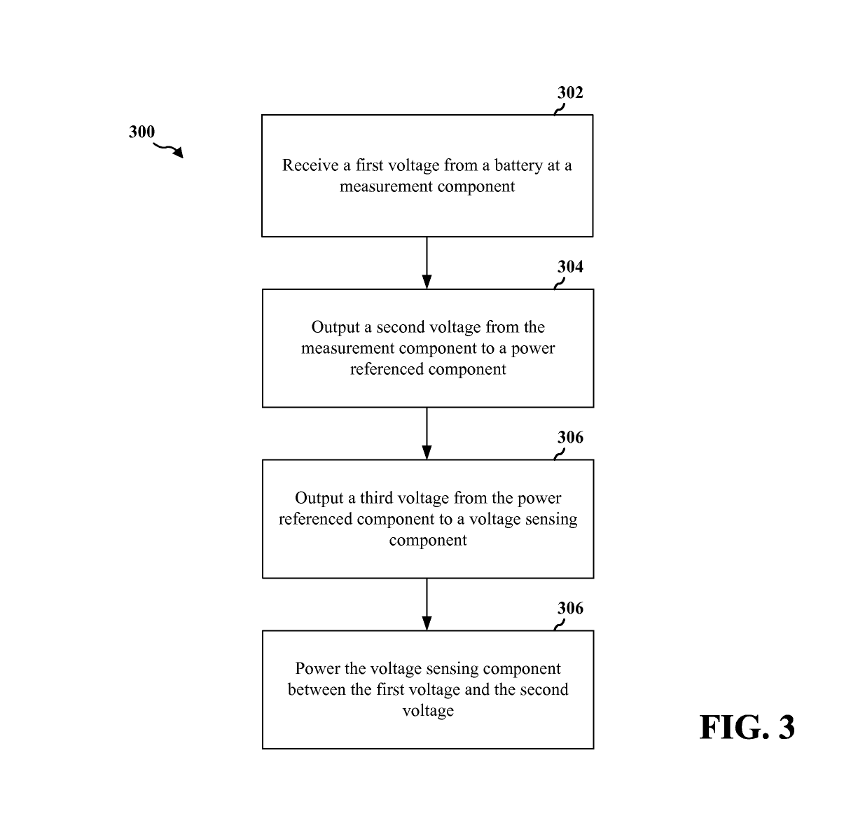

FIG. 3 is a flow chart 300 of reducing a common mode variation experienced by a ADC. At step 302, a first voltage is received from a battery at a source of a measurement component. The first voltage may be received from the top side of the battery, e.g., as illustrated in FIG. 1. At step 304, a second voltage is output from the measurement component to a power referenced component. The second voltage tracks the first voltage. At step 306, a third voltage is output from the power referenced component to a voltage sensing component, the third voltage being equal to the second voltage less a predetermined voltage amount. The predetermined voltage amount may be approximately 1.8 V.

At step 308, the voltage sensing component is powered between the first voltage and the second voltage.

The measurement component may comprise at least one of a BATFET and an external sensing resistor, such as BATFET 103 and resistor 102 in FIG. 1. The power referencing component may comprise a power referenced LDO, such as LDO 104 in FIG. 1. The power referenced LDO may receive the first voltage as an input voltage. The voltage sensing component may comprise an ADC that receives an output between source and drain of BATFET or both sides of an external resistor (Rₛ), such as ADC 106 in FIG. 1.

The measurement component, the voltage sensing component ADC, and power referenced component may be comprised in a PMIC, as illustrated in FIG. 1.

The apparatus may be configured as a fuel gauge for the battery. In this example application, the method may further include outputting a measured voltage Vsense from the measurement component indicating a fuel level of the battery.

The battery may be external to the PMIC, and an exterior bypass capacitor may connect the power referenced component to the exterior of the PMIC.

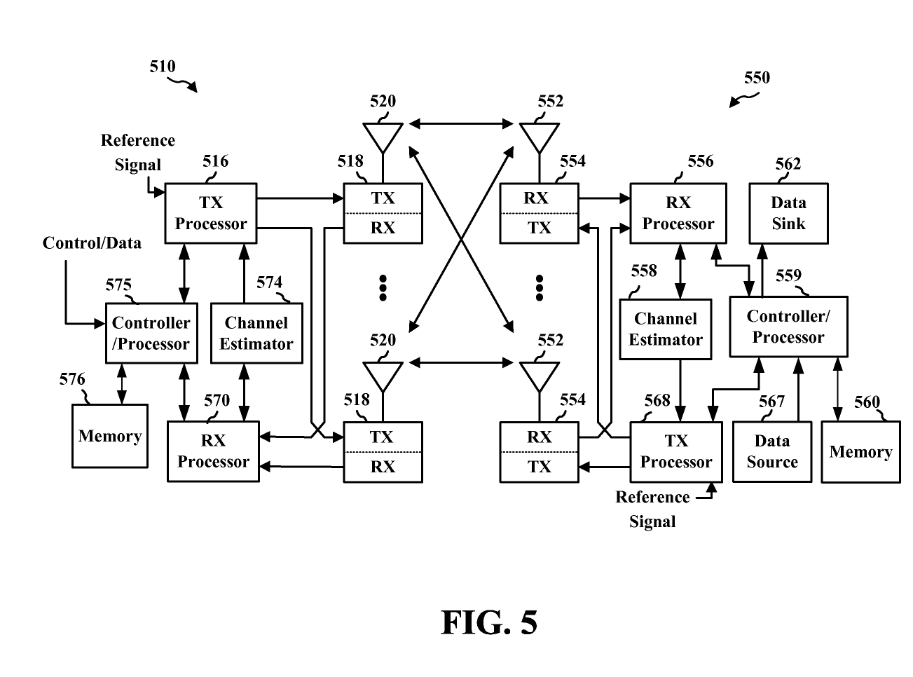

The apparatus may be comprised in a UE. Thus, the method 300 may be performed by a UE such as UE 550 illustrated in FIG. 5.

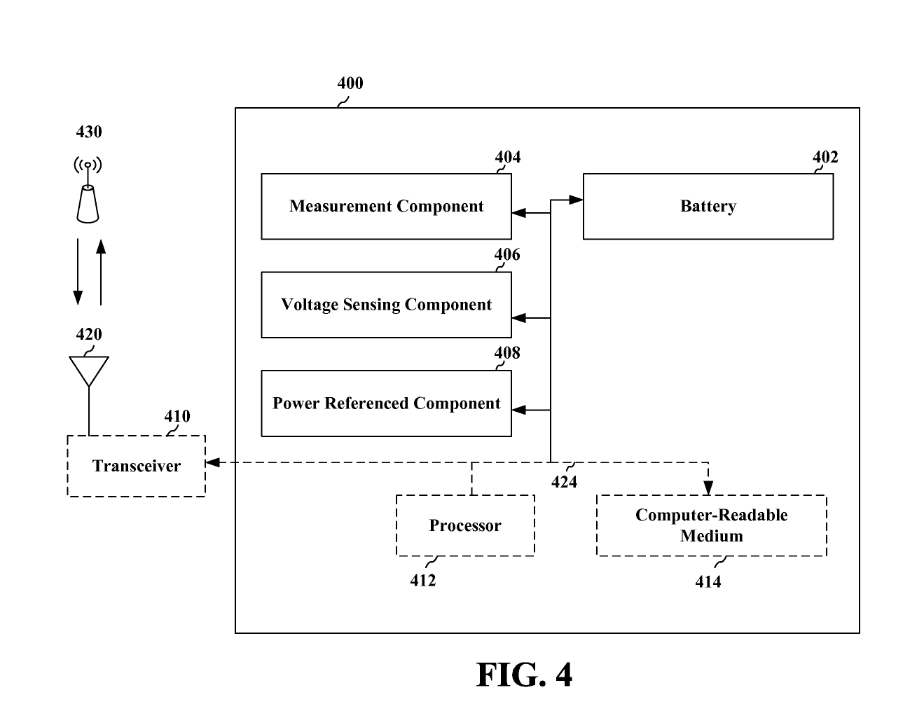

FIG. 4 is a diagram illustrating an example of a hardware implementation for an apparatus 400 for reducing a CMMR, as described above. The apparatus comprises a connection to a battery 402. The battery has a voltage VPH_PWR. The apparatus comprises a measurement component 404 that receives, at its source, a voltage from the top of the battery. The apparatus comprises a voltage sensing component 406 powered by the voltage from the battery. The apparatus comprises a power referenced component 408 that tracks the voltage from the battery and outputs the tracked voltage minus a predetermined voltage amount to a negative side of the voltage sensing component. The predetermined voltage amount may be, e.g., approximately 1.8 V.

The measurement component 404 may comprise at least one of a BATFET and an external sensing resistor (Rₛ), such as BATFET 103 and resistor 102 illustrated in FIG. 1. The power referenced component may comprise a power referenced LDO, e.g., LDO 104. The power referenced LDO may receive an input voltage from VPH_PWR 105. The voltage sensing component 406 may comprise a CCADC, e.g. 106, powered from VPH_PWR and an output of the LDO as illustrated in FIG. 1.

The measurement component 404, the voltage sensing component 406, and power referenced component 408 may be comprised in a PMIC. The battery 402 may be external to the PMIC and a bypass capacitor may connect the LDO to the exterior of the PMIC.

The apparatus may be configured to provide a fuel gauge for the battery 402, where the measurement component 404 outputs a measured voltage Vsense indicating a fuel level of the battery 402. The apparatus may also include a processor 412 and computer readable medium 414 for performing voltage sensing functions.

As noted above, the apparatus may be comprised within a UE. In this example, the UE may further comprise a transceiver 410 having an antenna 420 for communicating with node 430.

FIG. 5 is a block diagram of an evolved Node B (eNB) 510 in communication with UE 550 in an access network. Aspects presented herein may be applied to UE 550. As an example, aspects may be applied in order to provide an accurate fuel gauge for UE 550. In the downlink (DL), upper layer packets from the core network are provided to a controller/processor 575. The controller/processor 575 implements the functionality of the L2 layer. In the DL, the controller/processor 575 provides header compression, ciphering, packet segmentation and reordering, multiplexing between logical and transport channels, and radio resource allocations to the UE 550 based on various priority metrics. The controller/processor 575 is also responsible for hybrid automatic repeat request (HARQ) operations, retransmission of lost packets, and signaling to the UE 550.

The transmit (TX) processor 516 implements various signal processing functions for the L1 layer (i.e., physical layer). The signal processing functions includes coding and interleaving to facilitate forward error correction (FEC) at the UE 550 and mapping to signal constellations based on various modulation schemes (e.g., binary phase-shift keying (BPSK), quadrature phase-shift keying (QPSK), M-phase-shift keying (M-PSK), M-quadrature amplitude modulation (M-QAM)). The coded and modulated symbols are then split into parallel streams. Each stream is then mapped to an orthogonal frequency division multiple access (OFDM) subcarrier, multiplexed with a reference signal (e.g., pilot) in the time and/or frequency domain, and then combined together using an Inverse Fast Fourier Transform (IFFT) to produce a physical channel carrying a time domain OFDM symbol stream. The OFDM stream is spatially precoded to produce multiple spatial streams. Channel estimates from a channel estimator 574 may be used to determine the coding and modulation scheme, as well as for spatial processing. The channel estimate may be derived from a reference signal and/or channel condition feedback transmitted by the UE 550. Each spatial stream is then provided to a different antenna 520 via a separate transmitter 518TX. Each transmitter 518TX modulates an RF carrier with a respective spatial stream for transmission.

At the UE 550, each receiver 554RX receives a signal through its respective antenna 552. Each receiver 554RX recovers information modulated onto an RF carrier and provides the information to the receive (RX) processor 556. The RX processor 556 implements various signal processing functions of the L1 layer. The RX processor 556 performs spatial processing on the information to recover any spatial streams destined for the UE 550. If multiple spatial streams are destined for the UE 550, they may be combined by the RX processor 556 into a single OFDM symbol stream. The RX processor 556 then converts the OFDM symbol stream from the time-domain to the frequency domain using a Fast Fourier Transform (FFT). The frequency domain signal comprises a separate OFDM symbol stream for each subcarrier of the OFDM signal. The symbols on each subcarrier, and the reference signal, is recovered and demodulated by determining the most likely signal constellation points transmitted by the eNB 510. These soft decisions may be based on channel estimates computed by the channel estimator 558. The soft decisions are then decoded and deinterleaved to recover the data and control signals that were originally transmitted by the eNB 510 on the physical channel. The data and control signals are then provided to the controller/processor 559.

The controller/processor 559 implements the L2 layer. The controller/processor can be associated with a memory 560 that stores program codes and data. The memory 560 may be referred to as a computer-readable medium. In the UL, the controller/processor 559 provides demultiplexing between transport and logical channels, packet reassembly, deciphering, header decompression, control signal processing to recover upper layer packets from the core network. The upper layer packets are then provided to a data sink 562, which represents all the protocol layers above the L2 layer. Various control signals may also be provided to the data sink 562 for L3 processing. The controller/processor 559 is also responsible for error detection using an acknowledgement (ACK) and/or negative acknowledgement (NACK) protocol to support HARQ operations.

In the UL, a data source 567 is used to provide upper layer packets to the controller/processor 559. The data source 567 represents all protocol layers above the L2 layer. Similar to the functionality described in connection with the DL transmission by the eNB 510, the controller/processor 559 implements the L2 layer for the user plane and the control plane by providing header compression, ciphering, packet segmentation and reordering, and multiplexing between logical and transport channels based on radio resource allocations by the eNB 510. The controller/processor 559 is also responsible for HARQ operations, retransmission of lost packets, and signaling to the eNB 510.

Channel estimates derived by a channel estimator 558 from a reference signal or feedback transmitted by the eNB 510 may be used by the TX processor 568 to select the appropriate coding and modulation schemes, and to facilitate spatial processing. The spatial streams generated by the TX processor 568 are provided to different antenna 552 via separate transmitters 554TX. Each transmitter 554TX modulates an RF carrier with a respective spatial stream for transmission.

The UL transmission is processed at the eNB 510 in a manner similar to that described in connection with the receiver function at the UE 550. Each receiver 518RX receives a signal through its respective antenna 520. Each receiver 518RX recovers information modulated onto an RF carrier and provides the information to a RX processor 570. The RX processor 570 may implement the L1 layer.

The controller/processor 575 implements the L2 layer. The controller/processor 575 can be associated with a memory 576 that stores program codes and data. The memory 576 may be referred to as a computer-readable medium. In the UL, the control/processor 575 provides demultiplexing between transport and logical channels, packet reassembly, deciphering, header decompression, control signal processing to recover upper layer packets from the UE 550. Upper layer packets from the controller/processor 575 may be provided to the core network. The controller/processor 575 is also responsible for error detection using an ACK and/or NACK protocol to support HARQ operations.

Several aspects have been presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof Whether such elements are implemented as hardware or software depends upon the particular application and design constraints imposed on the overall system.

By way of example, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

Accordingly, in one or more exemplary embodiments, the functions described may be implemented in hardware, software, firmware, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, various aspects are described herein in connection with a terminal, which can be a wired terminal or a wireless terminal A terminal can also be called a system, device, subscriber unit, subscriber station, mobile station, mobile, mobile device, remote station, remote terminal, access terminal, user terminal, communication device, user agent, user device, or user equipment (UE). A wireless terminal may be a cellular telephone, a satellite phone, a cordless telephone, a Session Initiation Protocol (SIP) phone, a wireless local loop (WLL) station, a personal digital assistant (PDA), a handheld device having wireless connection capability, a computing device, or other processing devices connected to a wireless modem. Moreover, various aspects are described herein in connection with a base station. A base station may be utilized for communicating with wireless terminal(s) and may also be referred to as an access point, a Node B, or some other terminology.

Moreover, the term “or” is intended to man an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. An apparatus for reducing Common Mode variations experienced by a voltage sensing component, the apparatus comprising:
a battery having a voltage VPH_PWR;
a measurement component that receives, at its source, a voltage from the top of the battery;
a voltage sensing component powered by the voltage from the battery; and
a power referenced component that tracks the voltage from the battery and outputs the tracked voltage from the battery minus a predetermined voltage amount to a negative side of the voltage sensing component.

2. The apparatus of claim 1, wherein the measurement component comprises at least one of a Battery Field Effect Transistor (BATFET) and an external sensing resistor (Rₛ).

3. The apparatus of claim 2, wherein the power referenced component comprises a power referenced low dropout regulator (LDO).

4. The apparatus of claim 3, wherein the power referenced LDO receives an input voltage from VPH_PWR.

5. The apparatus of claim 3, wherein the voltage sensing component comprises a switched-cap sigma delta ADC powered from VPH_PWR and an output of the LDO.

6. The apparatus of claim 1, wherein the predetermined voltage amount is approximately 1.8 V.

7. The apparatus of claim 1, wherein the measurement component, the voltage sensing component, and the power referenced component are comprised in a power management integrated circuit (PMIC).

8. The apparatus of claim 7, wherein the apparatus is configured to provide a fuel gauge for the battery, and wherein the measurement component outputs a measured voltage Vsense indicating a fuel level of the battery.

9. The apparatus of claim 7, wherein the battery is external to the PMIC and a bypass capacitor connects the LDO to the exterior of the PMIC.

10. The apparatus of claim 1, wherein the apparatus is comprised in a UE.

11. A method of reducing a common mode variation experienced by a voltage sensing component, the method comprising:
receiving a first voltage from a battery at a source of a measurement component, wherein the first voltage is received from the top side of the battery;
outputting a second voltage from the measurement component to a power referenced component, wherein the second voltage tracks the first voltage;
outputting a third voltage from the power referenced component to a voltage sensing component, wherein the third voltage is equal to the second voltage less a predetermined voltage amount; and
powering the voltage sensing component between the first voltage and the second voltage.

12. The method of claim 11, wherein the measurement component comprises at least one of a Battery Field Effect Transistor (BATFET) and an external sensing resistor.

13. The method of claim 12, wherein the power referenced component comprises a power referenced low dropout regulator (LDO).

14. The method of claim 13, wherein the power referenced LDO receives the first voltage as an input voltage.

15. The method of claim 11, wherein the voltage sensing component comprises a Switched-cap sigma delta ADC that receives an output from at least one of between a source and a drain of a BATFET and both sides of an external resistor (Rₛ).

16. The method of claim 11, wherein the predetermined voltage amount is approximately 1.8 V.

17. The method of claim 11, wherein the measurement component, the voltage sensing component, and the power referenced component are comprised in a power management integrated circuit (PMIC).

18. The method of claim 17, wherein the measurement component is comprised in a fuel gauge for the battery, the method further comprising:
outputting a measured voltage Vsense from the measurement component indicating a fuel level of the battery.

19. The method of claim 18, wherein the PMIC is comprised in a UE.

20. The method of claim 17, wherein the battery is external to the PMIC, and wherein an exterior bypass capacitor connects to the power referenced component.
